(19) United States
(12) Patent Application Publication
(10) Pub. No.: US 2026/0288213 A1
(43) Pub. Date: Sep. 24, 2026

(54) Chassis Identification Switch

(71) Applicant: Dell Products L.P., Round Rock, TX (US)

(72) Inventors: Steven Michael Christensen, Austin, TX (US); Chun-Che Wang, Hsinchu City (TW)

(73) Assignee: Dell Products L.P., Round Rock, TX (US)

(21) Appl. No.: 19/085,916

(22) Filed: Mar. 20, 2025

(51) Int. Cl. G06F 1/18; G01R 31/52; H05K 1/02; H05K 5/02

(52) U.S. Cl. CPC G06F 1/182; G01R 31/52; H05K 1/0215; H05K 5/0286

(57) ABSTRACT

A system and method for detecting a chassis type is disclosed. A printed circuit board (PCB) is installed in an Information Handling System (IHS) chassis. The PCB has a grounding feature coupled to a chassis detection circuit. This circuit outputs a signal indicating whether the grounding feature is in contact with a ground contact on the chassis. IHS parameters are set to ensure proper configuration and operation for the PCB based on the detected chassis type. The PCB may be a motherboard, option module, or extension card, for example. The grounding feature may utilize a contact or dome switch.

### BACKGROUND

Information Handling Systems (IHS) generally process, compile, store, and/or communicate information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use. In addition, information handling systems may include a variety of hardware and software components that may be configured to process, store, and communicate information and may include one or more computer systems, data storage systems, and networking systems.

IHSs are generally built from a wide variety of components. Selecting components to include within an information handling system helps end users target the capabilities of the information handling system for planned tasks. Typically, an information handling system has a motherboard that couples to a chassis to support communication between information handling system components. A typical motherboard is a printed circuit board (PCB) that has one or more central processing unit (CPU) sockets to accept one or more CPUs for executing instructions. The CPU sockets interface through the motherboard with memory sockets that hold memory for storing information in support of executing instructions, such as DIMM sockets that hold DRAM modules. The motherboard can interface with a variety of other components, such as an embedded controller, a network interface module, a graphics processor and other types of chipset components supported by the motherboard that perform processing functions. Generally, components interface through the motherboard using standardized communications links, such as a PCI or PCIe bus.

In some instances, processing functions are performed by components located off the motherboard, such as components supported by daughterboards or option modules. Option modules typically include a PCB with function-specific components, such as graphics components or network communication components. Option modules generally include an interface that provides communication with the motherboard through the motherboard's communications link, such as a PCI or PCIe bus. By distributing functions to option modules, an IHS provides end users with greater flexibility for the selection of components. For example, a graphics subsystem built on an option module will typically provide more effective graphics processing than the graphics components included with a chipset coupled to a motherboard. As another example, a server adjusts to interface with local area networks and/or storage networks by inserting appropriate option modules for the desired interfaces.

### SUMMARY

Embodiments are directed to systems and methods for detecting the chassis type in which a PCB is installed. In one embodiment, a device includes a printed circuit board having a grounding feature on a first side with a chassis detection circuit coupled to the grounding feature. The grounding feature is configured to touch a ground contact on certain types of chassis. The chassis detection circuit outputs a signal that indicates whether such contact is present. The chassis detection circuit may be a pull-high design that outputs a low signal upon confirming contact with the ground contact. A PCB controller may be coupled to the chassis detection circuit output so as to identify a chassis type. The printed circuit board may be implemented, for example, as a motherboard, an option module, or an extension card. The grounding feature may take the form of a contact designed to engage a chassis bracket or may be a switch configured to contact a chassis wall when the device is installed.

In another embodiment, an information handling system comprises a printed circuit board installed in a chassis. The printed circuit board has a grounding feature on one side. A chassis detection circuit is coupled to the grounding feature. The chassis detection circuit is configured to determine whether the grounding feature is touching an intended chassis ground contact. The chassis ground contact may include a bracket mounted on the chassis wall. In some embodiments, the grounding feature is implemented as a contact that touches a chassis bracket. In other embodiments, the grounding feature is embodied as a switch configured to engage a chassis wall. The chassis detection circuit includes a pull-high configuration that outputs a low signal when contact is made. The chassis detection circuit outputs a high signal when contact is absent.

In yet another embodiment, a method for booting an information handling system comprises reading a chassis type signal from a printed circuit board, retrieving a chassis flag value from nonvolatile memory, and determining whether the chassis type signal matches the chassis flag value so as to allow the boot process to continue if a match is found. If a mismatch is detected, the method further comprises determining whether the system is in a manufacture mode. If the information handling system is not in the manufacture mode, a message is posted indicating that the printed circuit board is installed in the wrong chassis before continuing the boot process. In an example use case, the chassis type signal may be monitored to detect whether a printed circuit board is to set the appropriate fan speed control algorithms, which may be different for each chassis.

In an alternative embodiment, when a mismatch between the chassis type signal and the chassis flag value is encountered while in manufacture mode, the chassis flag value changed in nonvolatile memory, chassis parameters associated with the printed circuit board are set as appropriate for the chassis, and a reboot process is initiated. In some implementations, the chassis type signal is read from a chassis detection circuit coupled to the grounding feature, which may be a contact configured to engage a chassis bracket when the printed circuit board is installed in a selected chassis type.

These and other features will be more clearly understood from the following detailed description and the accompanying drawings.

### BRIEF DESCRIPTION OF THE DRAWINGS

Having thus described the invention in general terms, reference will now be made to the accompanying drawings, which are not necessarily drawn to scale, and wherein:

FIG. 1 illustrates an example printed circuit board assembly (PCBA) that may be configured to work with different IHS chassis architectures.

FIG. 2 illustrates a bottom side of PCBA of FIG. 1 with a grounding feature according to an example embodiment.

FIG. 3 is a schematic of a chassis-type detection circuit according to an example embodiment.

FIGS. 4A-4C illustrate various embodiments using a grounding point on an IHS chassis to determine which chassis type is associated with a PCBA.

FIGS. 5A-5D illustrate alternative chassis detection embodiments using a dome switch.

FIG. 6 is a flowchart illustrating a BIOS workflow process according to an example embodiment.

### DETAILED DESCRIPTION

The invention now will be described more fully hereinafter with reference to the accompanying drawings. This invention may, however, be embodied in many different forms and should not be construed as limited to the embodiments set forth herein. Rather, these embodiments are provided so that this disclosure will be thorough and complete, and will fully convey the scope of the invention to those skilled in the art. One skilled in the art may be able to use the various embodiments of the invention.

Various architectures may be used for different IHSs, such as different configurations designed for specific use cases, performance requirements, and spatial constraints. The dimensions of an IHS chassis vary for different architectures, which affects how the IHS components are arranged and installed in the chassis. Example architectures include, for example, Full Tower, Mid Tower, Mini Tower, Small Form Factor, and Horizontal/Desktop Form Factor. The specific IHS components, such as CPUs, GPUs, memory, storage, fans or other cooling solutions, etc., depend on the user's needs, available space, performance demands, and upgradeability. An IHS chassis will often have a baseline configuration that allows for additional features and capabilities using expansion slots.

Printed Circuit Board Assemblies (PCBA) serve as the foundation for electronic circuits in IHS systems. The PCBAs consist of a Printed Circuit Board (PCB) that is populated with electronic components such as processors, microchips, resistors, capacitors, and connectors that enable a desired functionality. The PCBA provides power distribution, data pathways, and control signals for the various components mounted on the PCB. PCBAs provide functionality for graphics cards (GPUs), power supply units, storage devices such as solid state devices (SSDs) and hard disk drives (HDDs), networking components such as network interface cards (NICs), modems, and routers, and fan and cooling systems. The PCBAs form the backbone of the IHS and enable the integration and operation of essential components. The PCBA may be a motherboard or may be part of an option module/daughtercard that connects to the motherboard directly or through an expansion slot.

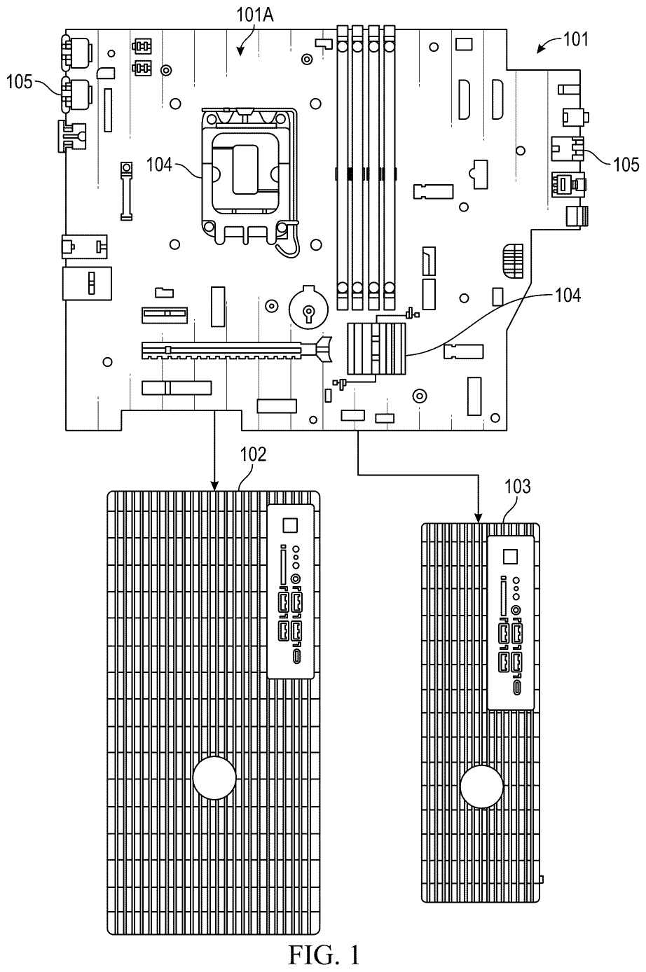

As illustrated in FIG. 1, a PCBA 101 may be configured to work with different IHS chassis architectures 102, 103. This allows customers to order the IHS chassis 102 or 103 that fits their needs and to take advantage of specific features and functionality provided by PCBA 101. The PCBA 101 is installed at the factory during manufacture or later added during a service call. It is important for the IHS to know the chassis type in which the PCBA has been installed. This may be required for model tracking, configuring input/output setting and for cooling system control algorithms. Alternatively, a PCBA may be configured only in a particular chassis type or group of chassis. In that case, it is important to detect whether the PCBA has been installed in the wrong chassis.

Generally, PCBAs 101, such as graphics cards, sound cards, network cards, and expansion cards, are installed or replaced while the IHS is powered off to prevent damage to both the PCBA hardware and the system. Example PCBA 101 has a top side 101a where a number of components 104 and connectors 105 are installed. When an IHS is powered on, components 104 and connectors 105 are actively conducting electricity. So, installing PCBA 101 while the system is running would cause short circuits, electrical surges, or static discharge, which may permanently damage the PCBA 101.

When the IHS is powered on after PCBA 101 install, the BIOS (Basic Input/Output System) or UEFI (Unified Extensible Firmware Interface) runs a Power-On Self-Test (POST). During POST, the IHS checks for new hardware, such as RAM, storage devices, expansion cards, and PCBA 101. The IHS scans for devices connected to the Peripheral Component Interconnect Express (PCIe) bus or to expansion slots. The BIOS/UEFI assigns system resources to a new PCBA 101, such as I/O ports, memory addresses, Interrupt Requests (IRQ), and DMA channels if required. Once the Operating System (OS) boots up, it queries the PCI bus and identifies the newly installed PCBA 101. The OS then loads the appropriate driver for the PCBA 101 as needed and initializes the PCBA 101.

PCBA 101 may function in different ways (e.g., offer different features or require different system support or cooling) depending upon the type of chassis in which PCBA 101 is installed. The embodiments disclosed herein allow the PCBA 101 to passively detect a chassis type and to provide feedback to a BIOS/UEFI or OS, which can be used to activate chassis-appropriate features or to identify when PCBAs are installed in the wrong chassis type.

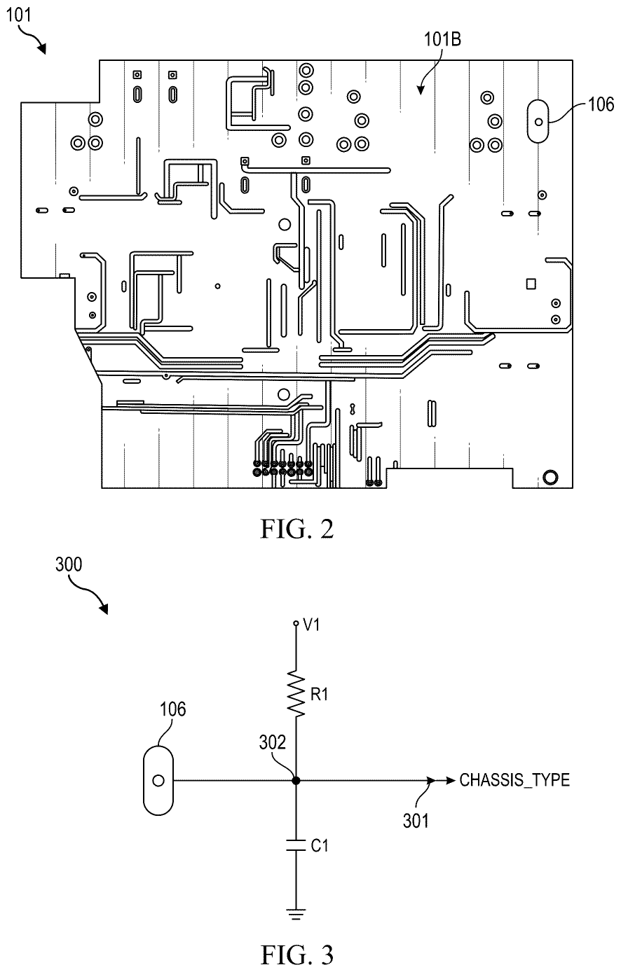

FIG. 2 illustrates a bottom side 101b of PCBA 101 according to an example embodiment. Bottom side 101b or the back side of PCBA 101 as shown includes traces and contacts for the components 104 and connectors 105 on top side 101a. PCBA 101 also includes a grounding feature 106, such as an electrical contact, plated area, or any general purpose input/output (GPIO), on bottom surface 101b. Often, PCBA 101 is installed in an IHS chassis so that bottom side 101b is adjacent to a chassis wall or other chassis structural component, which exposes top side 101a and components 104 to air from cooling fans. This configuration places grounding feature 106 near the chassis wall or other chassis structural component. Typically, the walls of an IHS chassis are electrically coupled to ground. Accordingly, if grounding feature 106 touches the chassis wall, then the grounding feature 106 will be driven to the ground state or zero voltage.

In an example embodiment, grounding feature 106 may be monitored to detect when it is grounded, such as by contacting an IHS chassis wall. This information can then be used to determine whether the associated PBCA is installed in a particular chassis. For example, PCBA 101 is configured for installation in two different chassis, then the voltage status of grounding feature 106 may be used to determine which chassis has PCBA 101 installed.

FIG. 3 illustrates a chassis-type detection circuit 300 according to an example embodiment. Circuit 300 is a pull-high design that normally generates a voltage-high signal (or other non-zero voltage) at CHASSIS_TYPE output 301, which is reading the voltage at node 302. Voltage V1 is applied across resistor R1, which is arranged in series with capacitor C1. Without an input applied to grounding feature 106, node 302 will maintain voltage V1, which can be detected at CHASSIS_TYPE output 301. In an example configuration, V1 is 3 V, R1 is 10 KΩ, and C1 is 100 nF, which provides a 3 V output at 301 when there is no other voltage or signal applied to grounding feature 106. Otherwise, if a voltage is applied to grounding feature 106, then the output at 301 be at the same voltage as grounding feature 106.

Therefore, as long as the output voltage 301 is pulled-high to V1, circuit 300 indicates that grounding feature 106 is not grounded. However, when grounding feature touches a chassis wall or other grounded chassis component (i.e., a component at zero voltage), then node 302 will be pulled-down or pulled-low and driven to ground voltage. This will change the output voltage 301 to zero voltage. Accordingly, when monitoring output CHASSIS_TYPE output 301, the appearance of a zero voltage indicates that grounding feature 106 is now in contact with a chassis wall or other grounded chassis component.

The chassis-type detection circuit 300 may be a component of a PCBA, such as motherboard or option module. The CHASSIS_TYPE output 301 signal may be provided to a PCBA controller, such as a Platform Controller Hub (PCH) or an Embedded Controller (EC), that monitors the signal and provides further information to the IHS, such as notifications of a chassis type or warnings of a mismatched chassis type.

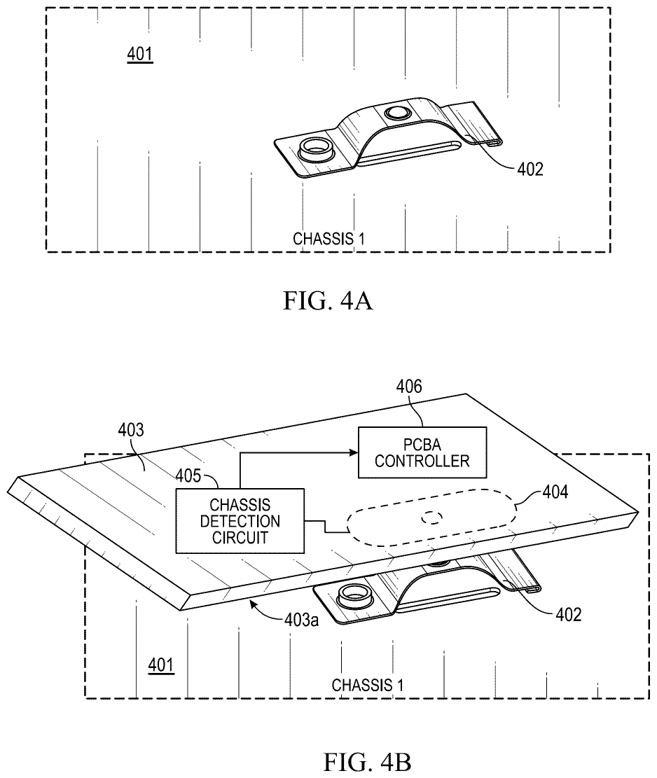

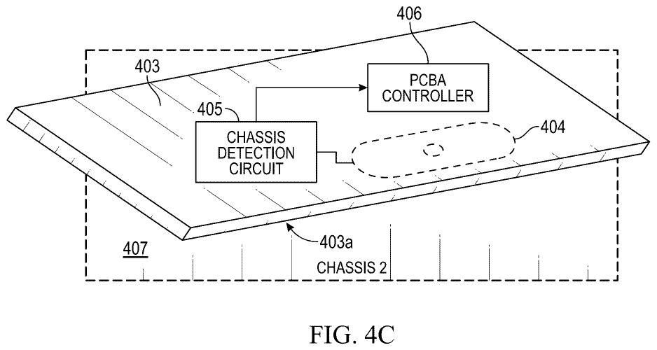

FIGS. 4A-4C illustrate various embodiments using a grounding point on an IHS chassis to determine which chassis type is associated with a PCBA. FIG. 4A illustrates a chassis component 401, such as a chassis wall, bracket, post, or case, in a first chassis architecture (Chassis 1). A PCBA detection bracket 402 is attached to chassis component 401 and electrically connected to the chassis'potential voltage, which is typically ground or zero voltage.

FIG. 4B illustrates a PCBA 403 installed in Chassis 1. A grounding feature 404 is mounted on the bottom side 403a of PCBA 403. When installed properly in Chassis 1, grounding feature 404 contacts detection bracket 402, which drives grounding feature 404 to zero voltage. Grounding feature 404 provides an input to chassis-detection circuit 405 (such as circuit 300). The output of chassis-detection circuit 405 is provided as an input to PCBA controller 406. In FIG. 4B, grounding feature 404 is at zero voltage due to contact with detection bracket 402, which drives the output of chassis-detection circuit 405 to zero voltage. Upon detecting the zero voltage input from chassis-detection circuit 405, PCBA controller 406 knows that PCBA 403 is installed in a Chassis 1 type IHS chassis. PCBA controller 406 then sets system parameters as appropriate for an IHS using the features of PCBA 403 in Chassis 1 environment.

FIG. 4C illustrates PCBA 403 installed in a second chassis architecture (Chassis 2) near a chassis component 407, such as a chassis wall, bracket, post, or case. The Chassis 2 architecture is different from the Chassis 1 architecture (e.g., having a different size, power, cooling capability, etc.) and does not include a detection bracket 402. When installed properly in Chassis 2, grounding feature 404 does not electrically contact the chassis structure. Therefore, grounding feature 404 as installed in Chassis 2 does not provide an input to chassis-detection circuit 405. Accordingly, the output of chassis-detection circuit 405 remains at a high signal voltage, which is provided as an input to PCBA controller 406. Upon detecting the high signal voltage input from chassis-detection circuit 405, PCBA controller 406 knows that PCBA 403 is installed in a Chassis 2 type IHS chassis. PCBA controller 406 then sets system parameters as appropriate for an IHS using the features of PCBA 403 in Chassis 2 environment.

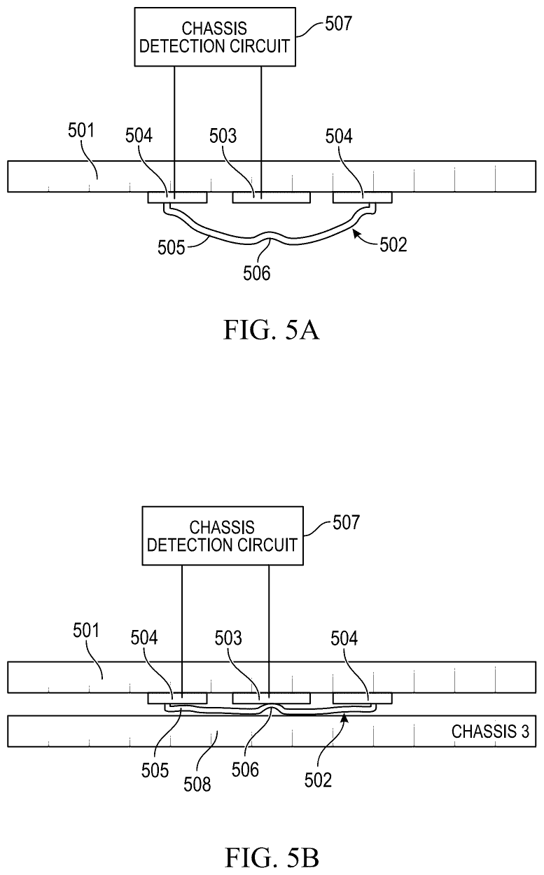

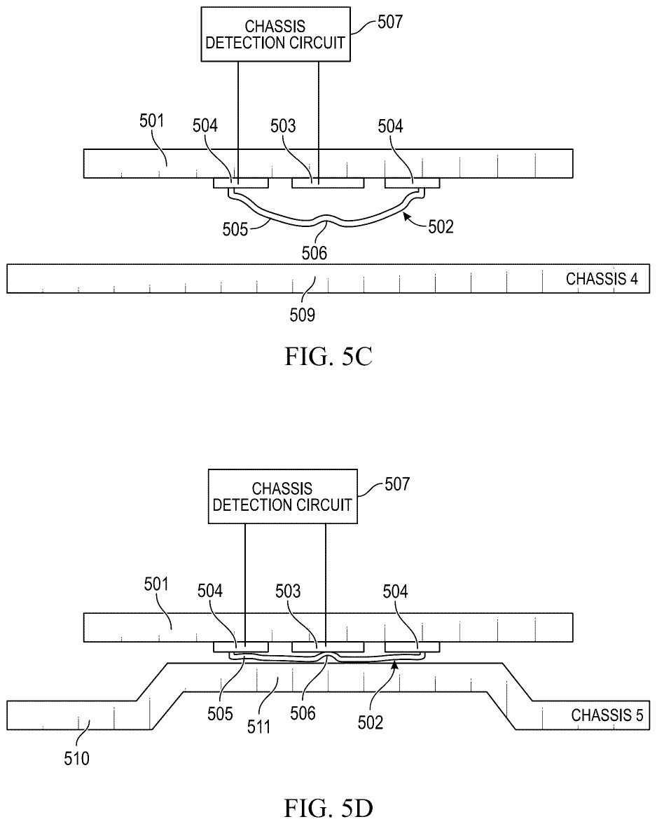

FIGS. 5A-5D illustrate alternative chassis detection embodiments. FIG. 5A illustrates an uninstalled PCBA 501 having a switch 502, such as a dome switch or other contact switch. Switch 502 includes a center contact 503 and edge contacts 504. A flexible dome portion 505 extends between the edge contacts 504. A detent feature 506 in the center of dome portion 505 extends toward center contact 503. Under force, flexible dome portion will deflect toward PCBA 501 so that detent feature 506 touches center contact 503. The components of dome switch are metal and, therefore, create electrical paths when touching. FIG. 5A shows dome switch 502 in the open position where detent feature 506 is not touching center contact 503. A chassis detection circuit 507 may be coupled to dome switch 502 so that dome switch provides an input to the chassis detection circuit 507.

FIG. 5B illustrates PCBA 501 installed in a third chassis architecture (Chassis 3) near a chassis component 508, such as a chassis wall, bracket, post, or case. Installation of PCBA 501 in Chassis 3 causes dome switch 502 to depress so that detent feature 506 touches center contact 503. This may be detected as a switch-closed input by chassis detection circuit 507, which in turn may provide inputs to a controller that uses the information to set system parameters as appropriate for PCBA 501 when used in Chassis 3.

FIG. 5C illustrates PCBA 501 installed in a fourth chassis architecture (Chassis 4) near a chassis component 509. Installation of PCBA 501 in Chassis 4 does not cause dome switch 502 to depress or close. So, in Chassis 4, detent feature 506 does not touch center contact 503. This may be detected as a switch-open input by chassis detection circuit 507, which in turn may provide inputs to a controller that uses the information to set system parameters as appropriate for PCBA 501 when used in Chassis 4.

FIG. 5D illustrates PCBA 501 installed in a fifth chassis architecture (Chassis 5) near a chassis component 510 having a chassis-detection feature 511. For example, component 501 may be a chassis wall, and feature 511 may be a detent, catch, ridge, or bracket formed in wall 501. Installation of PCBA 501 in Chassis 5 causes dome switch 502 to depress so that detent feature 506 touches center contact 503. This may be detected as a switch-closed input by chassis detection circuit 507, which in turn may provide inputs to a controller that uses the information to set system parameters as appropriate for PCBA 501 when used in Chassis 5.

The dome switch 502 is closed by different chassis architectures (Chassis 3 and Chassis 5) in FIGS. 5B and 5D. On the other hand, dome switch 502 is not closed in FIG. 5C (Chassis 4). This may be useful in a situation where Chassis 3 and 5 represent one group of ISHs, and Chassis 4 represents a different type of IHS. For example, if Chassis 4 supports cooling for high-power components during normal operation but Chassis 3 and 5 normally operate with lower cooling requirements, then Chassis 3 and 5 may need to know when PCBA 501 is installed so that the cooling system is adjusted to handle an additional temperature load.

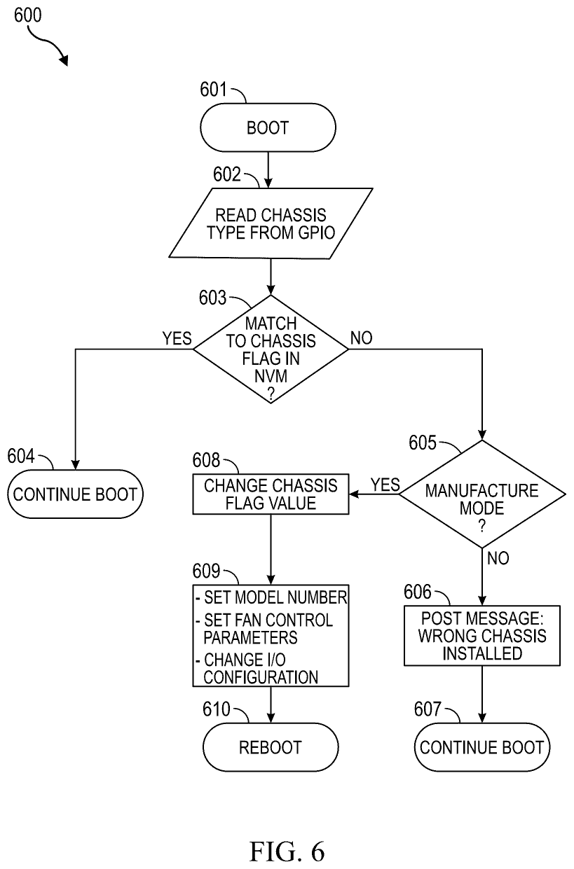

FIG. 6 is a flowchart illustrating a BIOS workflow process 600 according to an example embodiment. In step 601, an IHS is turned on and begins the boot process. In step 602, the BIOS reads the chassis type from a GPIO. The chassis-type information may be an output of a chassis detection circuit 405 or 507, for example. In step 603, the detected chassis type from step 602 is compared to a chassis flag stored in nonvolatile memory (NVM). If the detected chassis type matches the stored chassis flag (i.e., the installed PCBA is in the expected chassis), then the normal boot process continue at step 604

If the detected chassis type does not match the stored chassis flag in step 603 (i.e., the installed PCBA is not in an expected chassis), then the process moves to step 605 where the BIOS determines if the IHS is operating in a manufacture mode. If the IHS is not operating in a manufacture mode in step 605, then the process moves to step 606 where the BIOS posts a warning message indicating that the installation is in the wrong chassis. This may be an alert to a current user who executed the boot. This situation may occur, for example, if a user installed a new PCBA or moved a motherboard to a new chassis pre-boot. After issuing the warning in step 606, then the normal boot process continue at step 607.

If the IHS is operating in a manufacture mode in step 605, then the process moves to step 608 and the BIOS changes the stored chassis flag in NVM. In step 609, the BIOS then sets updated configuration data for the current PCBA/chassis combination, such as model number, fan control parameters, and I/O configuration. The process then continues to step 610 and the boot process is restarted (reboot), which will cause the BIOS to return to step 601 and begin process 600 again.

Process 600 may be used with a motherboard or PCBA having a grounding feature or switch that is only activated in a selected chassis type(s). In an example arrangement, an exposed pulled-high GPIO pad on bottom side of the motherboard will be driven low when touching a grounding feature, such as a bracket on a chassis. The GPIO will remain high when there is no grounding feature in the installed chassis. The IHS BIOS determines chassis type by reading the GPIO and, if necessary, processes chassis dependent code changes. The chassis-type change is only allowed in the factory environment with BIOS in manufacture mode. In the field, chassis-type detection can be used to notify a user that the motherboard is installed in the wrong chassis (i.e., mis-installed by the user) to prevent the IHS from working with degraded performance due to inappropriate system parameters, such as fan control, IO configuration, etc.

The GPIO provides a built-in detection mechanism that automatically identifies chassis type to allow BIOS appropriate chassis dependent settings including fan control, add-in card (AIC) slots, and model numbers. Chassis type is only changeable in manufacture mode, which provides flexible motherboard assembly into different chassis. After the system leaves the factory, chassis type detection will still work for warnings to the user when there is an unauthorized motherboard swap. The motherboard is re-useable and can be installed in different chassis by the authorized BIOS manufacture mode re-enabling, align to project goals.

An example chassis detection device includes a printed circuit board (PCB), a grounding feature on a first side of the PCB, and a chassis detection circuit coupled to the grounding feature. The grounding feature is configured to contact a ground contact on the chassis. The chassis detection circuit is configured to output a signal indicating whether the grounding feature is in contact with the ground contact. The chassis detection circuit includes a pull-high circuit. The chassis detection circuit is configured to output a low signal when the grounding feature is in contact with a ground contact on a chassis. The PCB may be a motherboard or an option module or an extension card, for example.

A device controller is coupled to an output of the chassis detection circuit. The device controller is configured to use the output of the chassis detection circuit to identify a chassis type.

The grounding feature is a contact configured to touch a chassis bracket when the device is installed in a chassis. Alternatively, the grounding feature is a switch configured to contact a chassis wall when the device is installed in a chassis.

In one arrangement, an information handling system (IHS) includes a printed circuit board (PCB) installed in an IHS chassis, a grounding feature on a first side of the PCB, and a chassis detection circuit coupled to the grounding feature. The chassis detection circuit is configured to determine whether the grounding feature is touching an IHS chassis ground contact. The grounding feature may be a contact configured to touch a chassis bracket when the device is installed in a chassis. Alternatively, the grounding feature may be a dome switch configured to contact a chassis wall when the device is installed in a chassis. The dome switch is closed upon contact with the chassis wall.

The chassis detection circuit is normally a pull-high circuit that is configured to output a low signal when the grounding feature is touching the IHS chassis ground contact. The chassis detection circuit is configured to output a high signal when the grounding feature is not touching the IHS chassis ground contact. The chassis ground contact may be a bracket mounted on an IHS chassis wall.

An example method for booting an information handling system (IHS) comprises reading a chassis type signal from a printed circuit board (PCB), retrieving a chassis flag value from nonvolatile memory in the IHS, determining whether the chassis type signal matches the chassis flag value, and allowing the IHS to continue a boot process if the chassis type signal matches the chassis flag value.

The method may further comprise determining whether the IHS is in a manufacture mode when the chassis type signal does not match the chassis flag value, posting a message indicating that the PCB is installed in the wrong chassis when the IHS is not in the manufacture mode, and continuing a boot process with the PCB installed.

The method may further comprise determining whether the IHS is in a manufacture mode when the chassis type signal does not match the chassis flag value, changing a chassis flag value in nonvolatile memory, setting chassis parameters associated with the PCB, and initiating a reboot process.

The chassis type signal may be read from a chassis detection circuit that is coupled to a grounding feature on the PCB. The grounding feature may be a contact configured to touch a chassis bracket when the PCB is installed in a selected chassis type.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated that the conception and specific embodiment disclosed may be readily utilized as a basis for modifying or designing other structures for carrying out the same purposes of the present invention. It should also be realized that such equivalent constructions do not depart from the invention set forth in the appended claims. The novel features which are believed to be characteristic of the invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present invention.

What is claimed is:

1. A device, comprising:
a printed circuit board (PCB);
a grounding feature on a first side of the PCB; and
a chassis detection circuit coupled to the grounding feature.

2. The device of claim 1, wherein the grounding feature is configured to contact a ground contact on a chassis, and wherein the chassis detection circuit is configured to output a signal indicating whether the grounding feature is in contact with the ground contact.

3. The device of claim 1, wherein the chassis detection circuit is a pull-high circuit.

4. The device of claim 3, wherein the chassis detection circuit is configured to output a low signal when the grounding feature is in contact with a ground contact on a chassis.

5. The device of claim 1, further comprising:
a device controller coupled to an output of the chassis detection circuit, wherein the device controller is configured to use the output of the chassis detection circuit to identify a chassis type.

6. The device of claim 1, wherein the PCB is a motherboard.

7. The device of claim 1, wherein the PCB is an option module or an extension card.

8. The device of claim 1, wherein the grounding feature is a contact configured to touch a chassis bracket when the device is installed in a chassis.

9. The device of claim 1, wherein the grounding feature is a switch configured to contact a chassis wall when the device is installed in a chassis.

10. An information handling system (IHS), comprising:
a printed circuit board (PCB) installed in an IHS chassis;
a grounding feature on a first side of the PCB; and
a chassis detection circuit coupled to the grounding feature, wherein the chassis detection circuit is configured to determine whether the grounding feature is touching an IHS chassis ground contact.

11. The IHS of claim 10, wherein the grounding feature is a contact configured to touch a chassis bracket when the device is installed in a chassis.

12. The IHS of claim 10, wherein the grounding feature is a dome switch configured to contact a chassis wall when the device is installed in a chassis.

13. The IHS of claim 10, wherein the chassis detection circuit is pull-high circuit that is configured to output a low signal when the grounding feature is touching the IHS chassis ground contact.

14. The IHS of claim 13, wherein the chassis detection circuit is configured to output a high signal when the grounding feature is not touching the IHS chassis ground contact.

15. The IHS of claim 10, wherein the IHS chassis ground contact is a bracket mounted on an IHS chassis wall.

16. A method for booting an information handling system (IHS), comprising:
reading a chassis type signal from a printed circuit board (PCB);
retrieving a chassis flag value from nonvolatile memory in the IHS;
determining whether the chassis type signal matches the chassis flag value; and
allowing the IHS to continue a boot process if the chassis type signal matches the chassis flag value.

17. The method of claim 16, further comprising:
determining whether the IHS is in a manufacture mode when the chassis type signal does not match the chassis flag value;
posting a message indicating that the PCB is installed in the wrong chassis when the IHS is not in the manufacture mode; and
continuing a boot process with the PCB installed.

18. The method of claim 16, further comprising:
determining whether the IHS is in a manufacture mode when the chassis type signal does not match the chassis flag value;
changing a chassis flag value in nonvolatile memory;
setting chassis parameters associated with the PCB; and
initiating a reboot process.

19. The method of claim 16, wherein the chassis type signal is read from a chassis detection circuit that is coupled to a grounding feature on the PCB.

20. The method of claim 19, wherein the grounding feature is a contact configured to touch a chassis bracket when the PCB is installed in a selected chassis type.
